(19) United States
(12) Patent Application Publication
(10) Pub. No.: US 2009/0186299 A1
(43) Pub. Date: Jul. 23, 2009

(54) Methods for imaging and processing negative-working imageable elements

(76) Inventors: Ting Tao, Fort Collins, CO (US); Eric E. Clark, Loveland, CO (US); Thomas R. Jordan, Windsor, CO (US)

Correspondence Address: Andrew J. Anderson;Patent Legal Staff, Eastman Kodak Company, 343 State Street, Rochester, NY, 14650-2201, US

(21) Appl. No.: 12/015,733

(22) Filed: Jan. 17, 2008

(51) Int. Cl. G03F 7/004; G03F 7/12

(52) U.S. Cl. 430/281.1; 430/302

(57) ABSTRACT

An imaged and developed element, such as a lithographic printing plate, is provided by infrared radiation imaging of a negative-working imageable element having a free radically polymerizable component, a free radical initiator composition, an infrared radiation absorbing compound, and adhesion promoter that is an organic compound having an ethylenically unsaturated carbon-carbon double bond that is connected to an alkoxysilyl or hydroxysilyl group. The use of the adhesion promoter provides increased printing durability for the imaged and developed element, especially those having sulfuric acid-anodized aluminum substrates.

### FIELD OF THE INVENTION

This invention relates to a method of imaging and processing negative-working imageable elements such as negative-working lithographic printing plate precursors. The invention also relates to methods of using these elements.

### BACKGROUND OF THE INVENTION

Radiation-sensitive compositions are routinely used in the preparation of imageable materials including lithographic printing plate precursors. Such compositions generally include a radiation-sensitive component, an initiator system, and a binder, each of which has been the focus of research to provide various improvements in physical properties, imaging performance, and image characteristics.

Recent developments in the field of lithographic printing plate precursors concern the use of radiation-sensitive compositions that can be imaged by means of lasers or laser diodes, and more particularly, that can be imaged and/or developed on-press. Laser exposure does not require conventional silver halide graphic arts films as intermediate information carriers (or “masks”) since the lasers can be controlled directly by computers. High-performance lasers or laser-diodes that are used in commercially-available image-setters generally emit radiation having a wavelength of at least 700 nm, and thus the radiation-sensitive compositions are required to be sensitive in the near-infrared or infrared region of the electromagnetic spectrum. However, other useful radiation-sensitive compositions are designed for imaging with ultraviolet or visible radiation.

There are two possible ways of using radiation-sensitive compositions for the preparation of printing plates. For negative-working printing plates precursors, exposed regions in the radiation-sensitive compositions are hardened and non-exposed regions are washed off during development. For positive-working printing plates precursors, the exposed regions are dissolved in a developer and the non-exposed regions become an image.

Various radiation-sensitive compositions and imageable elements are described in U.S. Pat. No. 6,309,792 (Hauck et al.), U.S. Pat. No. 6,893,797 (Munnelly et al.), U.S. Pat. No. 6,787,281 (Tao et al.), and U.S. Pat. No. 6,899,994 (Huang et al.), U.S. Patent Application Publication 2003/0118939 (West et al.), and EP 1,079,276A1 (Lilka et al.) and EP 1,449,650A1 (Goto). Other negative-working imageable elements are described, for example, in U.S. Pat. No. 6,916,595 (Fujimaki et al.), U.S. Pat. No. 6,702,437 (Fujimaki et al.), and U.S. Pat. No. 6,727,044 (Fujimaki et al.), Japanese Kokai 2000-187322 (Mitsubishi Chemical Co.), and U.S. Patent Application Publications 2004/0131972 (Fujimaki et al.), 2005/0031986 (Kakino et al.), 2006/0068328 (Aimura et al), and 2006/0199097 (Oda et al.).

EP 0 484 752A1 (Hase et al.) describes UV/visible-sensitive negative-working imageable elements having an oxygen barrier polyvinyl alcohol layer over the imageable layer. The imageable layer includes a silane coupling agent that may have a vinyl terminal group.

Silyl compounds are used in subbing layers in imageable elements described in U.S. Pat. No. 6,599,674 (Kawamura). U.S. Pat. No. 6,852,469 (Endo) describes imageable elements containing silane coupling groups that are attached to hydrophilic polymer backbones.

U.S. Pat. No. 7,014,983 (Patel et al.) describes positive-working imageable element containing copolymer binders in a top layer that contain silyl groups in side chains to improved resistance to pressroom chemicals.

### Problem to be Solved

The various negative-working compositions and elements described in the art can be readily used to prepare negative-working imageable elements. There is a need, however, to provide single-layer (no oxygen barrier topcoat) imageable elements that exhibit improved printing durability, especially when the imageable layer is applied to sulfuric acid-anodized aluminum-containing substrates. It is also desired that such elements would not require a post-exposure baking step.

### SUMMARY OF THE INVENTION

The present invention provides a negative-working, infrared radiation-sensitive imageable element comprising a substrate having thereon a single outermost imageable layer comprising:

a) an infrared radiation absorbing compound,

b) a free radically polymerizable component,

c) an initiator composition capable of generating free radicals sufficient to initiate polymerization of free radically polymerizable groups upon exposure to imaging radiation,

d) a polymeric binder, and

e) an adhesion promoter that is an organic compound having an ethylenically unsaturated carbon-carbon double bond that is connected to an alkoxysilyl or hydroxysilyl group.

In some embodiments, the negative-working, infrared radiation-sensitive imageable element is a lithographic printing plate precursor comprising a sulfuric acid-anodized aluminum-containing substrate having thereon a single outermost imageable layer comprising:

a) an infrared radiation absorbing dye,

b) a free radically polymerizable monomer or oligomer, or free radically crosslinkable polymer,

c) an initiator composition comprising an iodonium salt and optionally a co-initiator,

d) a polymeric binder, and

e) one or more of vinyltrimethoxysilane, vinylmethyldimethoxy-silane, vinyltriethoxysilane, vinyltris(2-methoxyethoxy)silane, vinyltriacetyloxy-silane, 3-acryloxypropyltrimethoxysilane, and 3-methacryloxypropyltrimethoxy-silane, 3-methacryloxypropylmethyldimethoxysilane, in a total amount of from about 0.2 to about 8 weight %.

This invention also provides a method of making an imaged element comprising:

A) imagewise exposing the negative-working imageable element of this invention using imaging infrared radiation to produce exposed and non-exposed regions, and

B) with or without a post-exposure baking step, developing the imagewise exposed element off-press to remove predominantly only the non-exposed regions.

The substrate can be an aluminum-containing substrate having a hydrophilic surface upon which the imageable layer is disposed, and the imaged and developed element can be a lithographic printing plate. The invention is especially advantageous when the aluminum-containing substrate has been anodized using sulfuric acid.

With the present invention, imaged negative-working imageable elements have increased printing durability, meaning that longer print runs can be achieved with satisfactory impressions. This advantage is achieved by incorporating an alkoxysilyl or hydroxysilyl adhesion promoter as described herein into the imageable layer that is the outermost layer of the element. In other words, no oxygen-barrier topcoat is needed and the post-exposure baking step, which is prevalent in the art, can be omitted.

### BRIEF DESCRIPTION OF THE DRAWING

FIG. 1 is a graphical representation of data obtained in Invention Example 1 and Comparative Example 1 described below.

### DETAILED DESCRIPTION OF THE INVENTION

### Definitions

Unless the context indicates otherwise, when used herein, the terms “imageable element”, “lithographic printing plate precursor”, and “printing plate precursor” are meant to be references to embodiments of the present invention.

In addition, unless the context indicates otherwise, the various components described herein such as “adhesion promoter”, “primary polymeric binder”, “initiator”, “co-initiator”, “free radically polymerizable component”, “infrared radiation absorbing compound”, “secondary polymeric binder”, and similar terms also refer to mixtures of such components. Thus, the use of the articles “a”, “an”, and “the” is not necessarily meant to refer to only a single component.

Moreover, unless otherwise indicated, percentages refer to percents by dry weight, for example, weight % based on total solids in a composition or formulation or dry layer composition.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

“Graft” polymer or copolymer refers to a polymer having a side chain that has a molecular weight of at least 200.

The term “polymer” refers to high and low molecular weight polymers including oligomers and includes homopolymers and copolymers.

The term “copolymer” refers to polymers that are derived from two or more different monomers.

The term “backbone” refers to the chain of atoms (carbon or heteroatoms) in a polymer to which a plurality of pendant groups are attached. One example of such a backbone is an “all carbon” backbone obtained from the polymerization of one or more ethylenically unsaturated polymerizable monomers. However, other backbones can include heteroatoms wherein the polymer is formed by a condensation reaction or some other means.

### Imageable Layers

The imageable elements include an infrared (IR) radiation-sensitive imaging composition disposed on a suitable substrate to form an imageable layer. The imageable elements may have any utility wherever there is a need for an applied coating that is polymerizable using suitable infrared radiation, and particularly where it is desired to remove unexposed regions of the coating instead of exposed regions. The IR radiation-sensitive compositions can be used to prepare an imageable layer in imageable elements such as printed circuit boards for integrated circuits, microoptical devices, color filters, photomasks, and printed forms such as lithographic printing plate precursors that are defined in more detail below.

The IR radiation-sensitive composition (and imageable layer) includes one or more free radically polymerizable components, each of which contains one or more free radically polymerizable groups that can be polymerized using free radical initiation. For example, such free radically polymerizable components can contain one or more free radical polymerizable monomers or oligomers having one or more addition polymerizable ethylenically unsaturated groups, crosslinkable ethylenically unsaturated groups, ring-opening polymerizable groups, azido groups, aryldiazonium salt groups, aryldiazosulfonate groups, or a combination thereof. Similarly, crosslinkable polymers having such free radically polymerizable groups can also be used.

Suitable ethylenically unsaturated components that can be polymerized or crosslinked include ethylenically unsaturated polymerizable monomers that have one or more of the polymerizable groups, including unsaturated esters of alcohols, such as acrylate and methacrylate esters of polyols. Oligomers and/or prepolymers, such as urethane acrylates and methacrylates, epoxide acrylates and methacrylates, polyester acrylates and methacrylates, polyether acrylates and methacrylates, and unsaturated polyester resins can also be used. In some embodiments, the free radically polymerizable component comprises carboxy groups.

Useful free radically polymerizable components include free-radical polymerizable monomers or oligomers that comprise addition polymerizable ethylenically unsaturated groups including multiple acrylate and methacrylate groups and combinations thereof, or free-radical crosslinkable polymers. Free radically polymerizable compounds include those derived from urea urethane (meth)acrylates or urethane (meth)acrylates having multiple polymerizable groups. For example, a free radically polymerizable component can be prepared by reacting DESMODUR® N100 aliphatic polyisocyanate resin based on hexamethylene diisocyanate (Bayer Corp., Milford, Conn.) with hydroxyethyl acrylate and pentaerythritol triacrylate. Useful free radically polymerizable compounds include NK Ester A-DPH (dipentaerythritol hexaacrylate) that is available from Kowa American, and Sartomer 399 (dipentaerythritol pentaacrylate), Sartomer 355 (di-trimethylolpropane tetraacrylate), Sartomer 295 (pentaerythritol tetraacrylate), and Sartomer 415 [ethoxylated (20)trimethylolpropane triacrylate] that are available from Sartomer Company, Inc.

Numerous other free radically polymerizable components are known to those skilled in the art and are described in considerable literature including Photoreactive Polymers: The Science and Technology of Resists, A Reiser, Wiley, New York, 1989, pp. 102-177, by B. M. Monroe in Radiation Curing: Science and Technology, S. P. Pappas, Ed., Plenum, New York, 1992, pp. 399-440, and in “Polymer Imaging” by A. B. Cohen and P. Walker, in Imaging Processes and Material, J. M. Sturge et al. (Eds.), Van Nostrand Reinhold, New York, 1989, pp. 226-262. For example, useful free radically polymerizable components are also described in EP 1,182,033A1 (Fujimaki et al.), beginning with paragraph [0170], and in U.S. Pat. No. 6,309,792 (Hauck et al.), U.S. Pat. No. 6,569,603 (Furukawa), and U.S. Pat. No. 6,893,797 (Munnelly et al.). The free radically polymerizable component can also include carboxy groups as described for example in U.S. Pat. No. 7,153,632 (Saraiya et al.).

Other useful free radically polymerizable components are non-polymeric or polymeric components having 1H-tetrazole groups and are also polymerizable in the presence of free radicals. Such components generally are mono-, di-, or triacrylates, or they are styryl compounds to which the 1H-tetrazole groups are attached. Such components are described in copending and commonly assigned U.S. Ser. No. 11/949,810 (filed Dec. 4, 2007 by Baumann, Dwars, Strehmel, Simpson, Savariar-Hauck, and Hauck) that is incorporated herein by reference.

The one or more free radically polymerizable components (monomeric, oligomeric, or polymeric) can be present in the imageable layer in an amount of at least 10 weight % and up to 70 weight %, and typically from about 20 to about 50 weight %, based on the total dry weight of the imageable layer. The weight ratio of the free radically polymerizable component to the total polymeric binders (described below) is generally from about 5:95 to about 95:5, and typically from about 10:90 to about 90:10, or even from about 30:70 to about 70:30.

The IR radiation-sensitive composition also includes an initiator composition that is capable of generating free radicals sufficient to initiate polymerization of all the various free radically polymerizable components upon exposure of the composition to imaging radiation. The initiator composition is generally responsive to infrared imaging radiation corresponding to the spectral range of at least 700 nm and up to and including 1400 nm (typically from about 750 to about 1200 nm). Initiator compositions are used that are appropriate for the desired imaging wavelengths).

In general, suitable initiator compositions comprise initiators that include but are not limited to, amines (such as alkanol amines), thiol compounds, N,N-dialkylaminobenzoic acid esters, N-arylglycines and derivatives thereof (such as N-phenylglycine), aromatic sulfonylhalides, trihalogenomethylsulfones, imides (such as N-benzoyloxyphthalimide), diazosulfonates, 9,10-dihydroanthracene derivatives, N-aryl, S-aryl, or O-aryl polycarboxylic acids with at least 2 carboxy groups of which at least one is bonded to the nitrogen, oxygen, or sulfur atom of the aryl moiety (such as aniline diacetic acid and derivatives thereof and other “co-initiators” described in U.S. Pat. No. 5,629,354 of West et al.), oxime ethers and oxime esters (such as those derived from benzoin), α-hydroxy or α-amino-acetophenones, trihalogenomethyl-arylsulfones, benzoin ethers and esters, peroxides (such as benzoyl peroxide), hydroperoxides (such as cumyl hydroperoxide), azo compounds (such as azo bis-isobutyronitrile), 2,4,5-triarylimidazolyl dimers (also known as hexaarylbiimidazoles, or “HABI's”) as described for example in U.S. Pat. No. 4,565,769 (Dueber et al.), trihalomethyl substituted triazines, boron-containing compounds (such as tetraarylborates and alkyltriarylborates) and organoborate salts such as those described in U.S. Pat. No. 6,562,543 (Ogata et al.), and onium salts (such as ammonium salts, diaryliodonium salts, triarylsulfonium salts, aryldiazonium salts, and N-alkoxypyridinium salts). For “violet”-sensitive compositions, the initiators are hexaarylbiimidazoles, oxime esters, or trihalomethyl substituted triazines.

Useful IR-sensitive initiator compositions can also include an onium salt including but not limited to, a sulfonium, oxysulfoxonium, oxysulfonium, sulfoxonium, ammonium, selenonium, arsonium, phosphonium, diazonium, or halonium salt. Further details of useful onium salts, including representative examples, are provided in U.S. Patent Application Publication 2002/0068241 (Oohashi et al.), WO 2004/101280 (Munnelly et al.), and U.S. Pat. Nos. 5,086,086 (Brown-Wensley et al.), U.S. Pat. No. 5,965,319 (Kobayashi), and U.S. Pat. No. 6,051,366 (Baumann et al.). For example, suitable phosphonium salts include positive-charged hypervalent phosphorus atoms with four organic substituents. Suitable sulfonium salts such as triphenylsulfonium salts include a positively-charged hypervalent sulfur with three organic substituents. Suitable diazonium salts possess a positive-charged azo group (that is —N═N⁺). Suitable ammonium salts include a positively-charged nitrogen atom such as substituted quaternary ammonium salts with four organic substituents, and quaternary nitrogen heterocyclic rings such as N-alkoxypyridinium salts. Suitable halonium salts include a positively-charged hypervalent halogen atom with two organic substituents. The onium salts generally include a suitable number of negatively-charged counterions such as halides, hexafluorophosphate, thiosulfate, hexafluoroantimonate, tetrafluoroborate, sulfonates, hydroxide, perchlorate, n-butyltriphenyl borate, tetraphenyl borate, and others readily apparent to one skilled in the art.

The halonium salts are useful such as the iodonium salts. In one embodiment, the onium salt has a positively-charged iodonium, (4-methylphenyl)[4-(2-methylpropyl)phenyl]-moiety and a suitable negatively charged counterion. Typically anions for the iodonium initiators are chloride, bromide, nitrated, perchlorate, hexafluorephosphate, tetrafluoroborate, tetraphenylborate, and triphenylbutylborate anions. A representative example of such an iodonium salt is available as Irgacure® 250 from Ciba Specialty Chemicals (Tarrytown, N.Y.) that is (4-methylphenyl)[4-(2-methylpropyl)phenyl]iodonium hexafluorophosphate and is supplied in a 75% propylene carbonate solution.

Useful boron-containing compounds include organic boron salts that include an organic boron anion such as those described in U.S. Pat. No. 6,569,603 (Furukawa) that is paired with a suitable cation such as an alkali metal ion, an onium, or a cationic sensitizing dye. Useful onium cations for this purpose include but are not limited to, ammonium, sulfonium, phosphonium, iodonium, and diazonium cations. They may be used alone or in combination with various co-initiators such as heterocyclic mercapto compounds including mercaptotriazoles, mercaptobenzimidazoles, mercaptobenzoxazoles, mercaptobenzothiazoles, mercaptobenzoxadiazoles, mercaptotetrazoles, such as those described for example in U.S. Pat. No. 6,884,568 (Timpe et al.) in amounts of at least 0.5 and up to and including 10 weight % based on the total solids of the radiation-sensitive composition. Useful mercaptotriazoles include 3-mercapto-1,2,4-triazole, 4-methyl-3-mercapto-1,2,4-triazole, 5-mercapto-1-phenyl-1,2,4-triazole, 4-amino-3-mercapto-1,2,4,-triazole, 3-mercapto-1,5-diphenyl-1,2,4-triazole, and 5-(p-aminophenyl)-3-mercapto-1,2,4-triazole.

Other useful initiator compositions include one or more azine compounds as described for example in U.S. Pat. No. 6,936,384 (Munnelly et al.). These compounds are organic heterocyclic compounds containing a 6-membered ring formed from carbon and nitrogen atoms. Azine compounds include heterocyclic groups such as pyridine, diazine, and triazine groups, as well as polycyclic compounds having a pyridine, diazine, or triazine substituent fused to one or more aromatic rings such as carbocyclic aromatic rings. Thus, the azine compounds include, for example, compounds having a quinoline, isoquinoline, benzodiazine, or naphthodiazine substituent. Both monocyclic and polycyclic azine compounds are useful.

Useful azine compounds are triazine compounds that include a 6-membered ring containing 3 carbon atoms and 3 nitrogen atoms such as those described in U.S. Pat. No. 6,309,792 (Hauck et al.), U.S. Pat. No. 6.010,824 (Komano et al.), U.S. Pat. No. 5,885,746 (Iwai et al), U.S. Pat. No. 5,496,903 (Watanabe et al.), and U.S. Pat. No. 5,219,709 (Nagasaka et al.).

The azinium form of azine compounds can also be used if desired. In azinium compounds, a quaternizing substituent of a nitrogen atom in the azine ring is capable of being released as a free radical. The alkoxy substituent that quaternizes a ring nitrogen atom of the azinium nucleus can be selected from among a variety of alkoxy substituents.

Halomethyl-substituted triazines, such as trihalomethyl triazines, are useful in the initiator composition. Representative compounds of this type include but are not limited to, 1,3,5-triazine derivatives such as those having 1 to 3 —CX₃ groups wherein X independently represent chlorine or bromine atoms, including polyhalomethyl-substituted triazines and other triazines, such as 2,4-trichloromethyl-6-methoxyphenyl triazine, 2-phenyl-4,6-bis(trichloromethyl)-s-triazine, 2,4,6-tris(trichloromethyl)-s-triazine, 2-methyl-4,6-bis(trichloromethyl)-s-triazine, 2-(styryl-4,6-bis(trichloromethyl)-s-triazine, 2-p-methoxystyryl)-4,6-bis(trichloromethyl)-s-triazine, 2-(4-methoxy-naphtho-1-yl)-4,6-bis(trichloromethyl)-s-triazine, 2-(4-ethoxynaphtho-lyl)-4,6-bis(trichloromethyl)-s-triazine, and 2-(4-(2-ethoxyethyl)-naphtho-1-yl)-4,6-bis(trichloromethyl)-s-triazine, 2-(4-methylthiophenyl)-4,6-bis(trichloromethyl)-2-triazine, 2-(4-chlorophenyl-4,6-bis(trichloromethyl)-2-triazine, 2,4,6-tri(trichloromethyl)-2-triazine, and 2,4,6-tri(tribromomethyl)-2-triazine.

The azine compounds may be used alone or in combination with one or more co-initiators such as titanocenes, mono- and polycarboxylic acids, hexaarylbisimidazoles, as described for example in U.S. Pat. No. 4,997,745 (Kawamura et al.).

Some particularly useful iodonium salts include the diaryliodonium borates in which the aryl groups of the cation can be substituted or unsubstituted. Possible substituents are described below in relation to Structure (IB). The borate anion has four valences filled with the same or different organic groups, for example, as described below for Structure (IBz).

Useful iodonium cations are well known in the art including but not limited to, U.S. Patent Application Publication 2002/0068241 (Oohashi et al.), WO 2004/101280 (Munnelly et al.), and U.S. Pat. No. 5,086,086 (Brown-Wensley et al.), U.S. Pat. No. 5,965,319 (Kobayashi), and U.S. Pat. No. 6,051,366 (Baumann et al.). For example, a useful iodonium cation includes a positively charged iodonium, (4-methylphenyl)[4-(2-methylpropyl)phenyl]-moiety and a suitable negatively charged borate counterion.

Useful diaryliodonium borates include, but are not limited to, those described in U.S. Patent Application Publication 2007/275322 (Tao et al.) or those represented by the following Structure (IB):

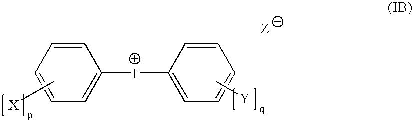

wherein X and Y are independently halo groups (for example, fluoro, chloro, or bromo), substituted or unsubstituted alkyl groups having 1 to 20 carbon atoms (for example, methyl, chloromethyl, ethyl, 2-methoxyethyl, n-propyl, isopropyl, isobutyl, n-butyl, t-butyl, all branched and linear pentyl groups, 1-ethylpentyl, 4-methylpentyl, all hexyl isomers, all octyl isomers, benzyl, 4-methoxybenzyl, p-methylbenzyl, all dodecyl isomers, all icosyl isomers, and substituted or unsubstituted mono-and poly-, branched and linear haloalkyls), substituted or unsubstituted alkyloxy having 1 to 20 carbon atoms (for example, substituted or unsubstituted methoxy, ethoxy, iso-propoxy, t-butoxy, (2-hydroxytetradecyl)oxy, and various other linear and branched alkyleneoxyalkoxy groups), substituted or unsubstituted aryl groups having 6 or 10 carbon atoms in the carbocyclic aromatic ring (such as substituted or unsubstituted phenyl and naphthyl groups including mono- and polyhalophenyl and naphthyl groups), or substituted or unsubstituted cycloalkyl groups having 3 to 8 carbon atoms in the ring structure (for example, substituted or unsubstituted cyclopropyl, cyclopentyl, cyclohexyl, 4-methylcyclohexyl, and cyclooctyl groups). Typically, X and Y are independently substituted or unsubstituted alkyl groups having 1 to 8 carbon atoms, alkyloxy groups having 1 to 8 carbon atoms, or cycloalkyl groups having 5 or 6 carbon atoms in the ring, and more preferably, X and Y are independently substituted or unsubstituted alkyl groups having 3 to 6 carbon atoms (and particularly branched alkyl groups having 3 to 6 carbon atoms). Thus, X and Y can be the same or different groups, the various X groups can be the same or different groups, and the various Y groups can be the same or different groups. Both “symmetric” and “asymmetric” diaryliodonium borate compounds are contemplated but the “symmetric” compounds (that is, they have the same groups on both phenyl rings) are useful.

In addition, two or more adjacent X or Y groups can be combined to form a fused carbocyclic or heterocyclic ring with the respective phenyl groups.

The X and Y groups can be in any position on the phenyl rings but typically they are at the 2- or 4-positions on either or both phenyl rings.

Despite what type of X and Y groups are present in the iodonium cation, the sum of the carbon atoms in the X and Y substituents generally is at least 6, and typically at least 8, and up to 40 carbon atoms. Thus, in some compounds, one or more X groups can comprise at least 6 carbon atoms, and Y does not exist (q is 0). Alternatively, one or more Y groups can comprise at least 6 carbon atoms, and X does not exist (p is 0). Moreover, one or more X groups can comprise less than 6 carbon atoms and one or more Y groups can comprise less than 6 carbon atoms as long as the sum of the carbon atoms in both X and Y is at least 6. Still again, there may be a total of at least 6 carbon atoms on both phenyl rings.

In Structure IB, p and q are independently 0 or integers of 1 to 5, provided that either p or q is at least 1. Typically, both p and q are at least 1, or each of p and q is 1. Thus, it is understood that the carbon atoms in the phenyl rings that are not substituted by X or Y groups have a hydrogen atom at those ring positions.

Z^{Θ} is an organic anion represented by the following Structure (IBz):

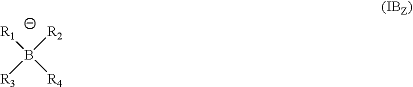

wherein R₁, R₂, R₃, and R₄ are independently substituted or unsubstituted alkyl groups having 1 to 12 carbon atoms (such as methyl, ethyl, n-propyl, iso-propyl, n-butyl, isobutyl, t-butyl, all pentyl isomers, 2-methylpentyl, all hexyl isomers, 2-ethylhexyl, all octyl isomers, 2,4,4-trimethylpentyl, all nonyl isomers, all decyl isomers, all undecyl isomers, all dodecyl isomers, methoxymethyl, and benzyl) other than fluoroalkyl groups, substituted or unsubstituted carbocyclic aryl groups having 6 to 10 carbon atoms in the aromatic ring (such as phenyl, p-methylphenyl, 2,4-methoxyphenyl, naphthyl, and pentafluorophenyl groups), substituted or unsubstituted alkenyl groups having 2 to 12 carbon atoms (such as ethenyl, 2-methylethenyl, allyl, vinylbenzyl, acryloyl, and crotonotyl groups), substituted or unsubstituted alkynyl groups having 2 to 12 carbon atoms (such as ethynyl, 2-methylethynyl, and 2,3-propynyl groups), substituted or unsubstituted cycloalkyl groups having 3 to 8 carbon atoms in the ring structure (such as cyclopropyl, cyclopentyl, cyclohexyl, 4-methylcyclohexyl, and cyclooctyl groups), or substituted or unsubstituted heterocyclyl groups having 5 to 10 carbon, oxygen, sulfur, and nitrogen atoms (including both aromatic and non-aromatic groups, such as substituted or unsubstituted pyridyl, pyrimidyl, furanyl, pyrrolyl, imidazolyl, triazolyl, tetrazoylyl, indolyl, quinolinyl, oxadiazolyl, and benzoxazolyl groups). Alternatively, two or more of R₁, R₂, R₃, and R₄ can be joined together to form a heterocyclic ring with the boron atom, such rings having up to 7 carbon, nitrogen, oxygen, or nitrogen atoms. None of the R₁ through R₄ groups contains halogen atoms and particularly fluorine atoms.

Typically, R₁, R₂, R₃, and R₄ are independently substituted or unsubstituted alkyl or aryl groups as defined above, and more typically, at least 3 of R₁, R₂, R₃, and R₄ are the same or different substituted or unsubstituted aryl groups (such as substituted or unsubstituted phenyl groups). For example, all of R₁, R₂, R₃, and R₄ can be the same or different substituted or unsubstituted aryl groups, or all of the groups are the same substituted or unsubstituted phenyl group. ZΘ can be a tetraphenyl borate wherein the phenyl groups are substituted or unsubstituted (for example, all are unsubstituted).

Representative iodoniun borate compounds include but are not limited to, 4-octyloxyphenyl phenyliodonium tetraphenylborate, [4-[(2-hydroxytetradecyl)-oxy]phenyl]phenyliodonium tetraphenylborate, bis(4-t-butylphenyl)iodonium tetraphenylborate, 4-methylphenyl-4′-hexylphenyliodonium tetraphenylborate, 4-methylphenyl-4′-cyclohexylphenyliodonium tetraphenylborate, bis(t-butylphenyl)iodonium tetrakis(pentafluorophenyl)borate, 4-hexylphenyl-phenyliodonium tetraphenylborate, 4-methylphenyl-4′-cyclohexylphenyliodonium n-butyltriphenylborate, 4-cyclohexylphenyl-phenyliodonium tetraphenylborate, 2-methyl-4-t-butylphenyl-4′-methylphenyliodonium tetraphenylborate, 4-methylphenyl-4′-pentylphenyliodonium tetrakis[3,5-bis(trifluoromethyl)phenyl]-borate, 4-methoxyphenyl-4′-cyclohexylphenyliodonium tetrakispenta-fluorophenyl)borate, 4-methylphenyl-4′-dodecylphenyliodonium tetrakis(4-fluorophenyl)borate, bis(dodecylphenyl)iodonium tetrakis(pentafluorophenyl)-borate, and bis(4-t-butylphenyl)iodonium tetrakis(1-imidazolyl)borate. Mixtures of two or more of these compounds can also be used in the iodonium borate initiator composition.

The diaryliodonium borate compounds can be prepared, in general, by reacting an aryl iodide with a substituted or unsubstituted arene, followed by an ion exchange with a borate anion. Details of various preparatory methods are described in U.S. Pat. No. 6,306,555 (Schulz et al.), and references cited therein, and by Crivello, J.Polymer Sci., Part A: Polymer Chemistry, 37, 4241-4254 (1999).

The free radical generating compounds in the initiator composition are generally present in the imageable layer in an amount of at least 0.5% and up to and including 30%, and typically at least 2 and up to and including about 20%, based on total dry weight of the imageable layer. The optimum amount of the various initiator components may differ for various compounds and the sensitivity of the radiation-sensitive composition that is desired and would be readily apparent to one skilled in the art.

The free radical generating compounds (initiators) may be used alone or in combination with various co-initiators such as heterocyclic mercapto compounds including mercaptotriazoles, mercaptobenzimidazoles, mercaptobenzoxazoles, mercaptobenzothiazoles, mercaptobenzoxadiazoles, mercaptotetrazoles, such as those described for example in U.S. Pat. No. 6,884,568 (Timpe et al.) in amounts of at least 0.5 and up to and including 10 weight % based on the total solids of the radiation-sensitive composition. Useful mercaptotriazoles include 3-mercapto-1,2,4-triazole, 4-methyl-3-mercapto-1,2,4-triazole, 5-mercapto-1-phenyl-1,2,4-triazole, 4-amino-3-mercapto-1,2,4,-triazole, 3-mercapto-1,5-diphenyl-1,2,4-triazole, and 5-p-aminophenyl)-3-mercapto-1,2,4-triazole.

Other useful co-initiators include metallocenes that are organometallic compounds having one or more cyclopentadienyl ligands that are optionally substituted at one or all of the ring carbons. Each carbon in the five-member ligand ring is coordinated to the transition metal center. Metallocenes are known for having a wide variety of transition metals including iron, titanium, tungsten, molybdenum, nickel, cobalt, chromium, zirconium, and manganese.

For example, ferrocenes have an iron center coordinated by at least one cyclopentadienyl ligand, but ferrocenes also include bicyclopentadienyl “sandwich” compounds. Suitable ferrocene compounds include those that have a hexhapto benzene ligand coordinated to the iron center. Examples of such compounds are described in Col. 7 of U.S. Pat. No. 6,936,384 (Munnelly et al.). Other suitable ferrocenes include compounds having halogenated, aryl-substituted, or haloaryl-substituted cyclopentadienyl ligands.

Titanocenes are also useful in the practice of this invention. Such compounds have a titanium center coordinated by at least one pentahapto cyclopentadienyl ligand and generally include additional ligands that may be known for organometallic complexes. Some suitable titanocene compounds include in their structures aryl ligands, haloaryl ligands, or pyrrole-substituted aryl ligands. Examples of useful titanocenes include those described in Col. 8 of U.S. Pat. No. 6,936,384 (noted above). One commercially available titanocene is (bis)cyclopentadienyl-(bis)2,6-difluoro-3-(pyrr-1-yl)phen-1-yl titanium sold by Ciba Specialty Chemicals as Irgacure® 784, as noted below with the Examples. Other suitable titanocenes are described in U.S. Pat. No. 4,548,891 (Riediker et al.), U.S. Pat. No. 4,590,287 (Riediker et al.), U.S. Pat. No. 5,008,302 (Husler et al.), U.S. Pat. No. 5,106,722 (Husler et al.), U.S. Pat. No. 6,010,824 (Komano et al.), and U.S. Pat. No. 6,153,660 (Fujimaki et al.).

Thus, several initiator/co-initiator combinations can be used in various embodiments of the present invention, including but not limited to:

a) a triazine as described above in combination with a co-initiator that is an N-aryl, S-aryl, or O-aryl polycarboxylic acids with at least 2 carboxy groups of which at least one is bonded to the nitrogen, oxygen, or sulfur atom of the aryl moiety (such as aniline diacetic acid and derivatives thereof) as described above,

b) a boron-containing counterion that comprises four of the same or different alkyl or aryl groups, or any combination thereof, wherein the boron-containing counterion is a counterion for an infrared radiation absorbing dye, or is a counterion in an onium salt,

c) a triazine as described above in combination with a co-initiator that is a mercaptan derivative as described above,

d) an onium salt (such as an iodonium salt) as described above in combination with a co-initiator that is a metallocene (for example a titanocene or ferrocene) as described for example in U.S. Pat. No. 6,936,384 (noted above) and EP 684,522A1 (Baumann et al.),

e) an iodonium salt (such as an iodonium borate) as described above in combination with a co-initiator that is a mercaptotriazole as described above,

f) a triazine as described above in combination with an alkyl triarylborate or a tetraarylborate,

g) a polyhaloalkyl-substituted compound or an azinium compound with a polycarboxylic acid, for example as described in EP 1,079,972 (noted above), and

h) a hexaarylbiimidazole and a heterocyclic mercapto compound, such as a mercaptotriazole.

The radiation-sensitive composition (and imageable element) generally includes one or more infrared radiation absorbing compounds (or chromophores or sensitizers) that absorb imaging radiation, or sensitize the composition to imaging infrared radiation having a λₘₐₓ of from about 700 nm and up to and including 1400 nm, and typically from about 700 to about 1200 nm. In some embodiments, the chromophore is cationic in nature.

Useful IR radiation absorbing chromophores include various IR-sensitive dyes (“IR dyes”). Examples of suitable IR dyes comprising the desired chromophore include but are not limited to, azo dyes, squarilium dyes, croconate dyes, triarylamine dyes, thioazolium dyes, indolium dyes, oxonol dyes, oxaxolium dyes, cyanine dyes, merocyanine dyes, phthalocyanine dyes, indocyanine dyes, indotricarbocyanine dyes, oxatricarbocyanine dyes, thiocyanine dyes, thiatricarbocyanine dyes, merocyanine dyes, cryptocyanine dyes, naphthalocyanine dyes, polyaniline dyes, polypyrrole dyes, polythiophene dyes, chalcogenopyryloarylidene and bi(chalcogenopyrylo)polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, squarine dyes, oxazole dyes, croconine dyes, porphyrin dyes, and any substituted or ionic form of the preceding dye classes. Suitable dyes are also described in U.S. Pat. No. 5,208,135 (Patel et al.), U.S. Pat. No. 6,153,356 (Urano et al.), U.S. Pat. No. 6,264,920 (Achilefu et al.), U.S. Pat. No. 6,309,792 (Hauck et al.), and U.S. Pat. No. 6,787,281 (Tao et al.), and EP 1,182,033A2 (noted above). Infrared radiation absorbing N-alkylsulfate cyanine dyes are described for example in U.S. Pat. No. 7,018,775 (Tao).

A general description of one class of suitable cyanine dyes is shown by the formula in paragraph [0026] of WO 2004/101280 (Munnelly et al.), incorporated herein by reference, and a useful IR absorbing compound is identified below with the Examples.

In addition to low molecular weight IR-absorbing dyes, IR dye chromophores bonded to polymers can be used as well. Moreover, IR dye cations can be used as well, that is, the cation is the IR absorbing portion of the dye salt that ionically interacts with a polymer comprising carboxy, sulfo, phospho, or phosphono groups in the side chains.

Near infrared absorbing cyanine dyes are also useful and are described for example in U.S. Pat. No. 6,309,792 (Hauck et al.), U.S. Pat. No. 6,264,920 (Achilefu et al.), U.S. Pat. No. 6,153,356 (Urano et al.), U.S. Pat. No. 5,496,903 (Watanate et al.). Suitable dyes may be formed using conventional methods and starting materials or obtained from various commercial sources including American Dye Source (Baie D'Urfe, Quebec, Canada) and FEW Chemicals (Germany). Other useful dyes for near infrared diode laser beams are described, for example, in U.S. Pat. No. 4,973,572 (DeBoer).

Other useful IR-sensitive dyes having the desired chromophore can be defined by the following Structure DYE-I:

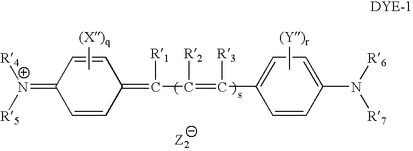

wherein R₁′, R₂′, and R₃′ each independently represents hydrogen, or a halo, cyano, substituted or unsubstituted alkoxy (having 1 to 8 carbon atoms, both linear and branched alkoxy groups), substituted or unsubstituted aryloxy (having 6 to 10 carbon atoms in the carbocyclic ring), substituted or unsubstituted acyloxy (having 2 to 6 carbon atoms), carbamoyl, substituted or unsubstituted acyl, substituted or unsubstituted acylamido, substituted or unsubstituted alkylamino (having at least one carbon atom), substituted or unsubstituted carbocyclic aryl groups (having 6 to 10 carbon atoms in the aromatic ring, such as phenyl and naphthyl groups), substituted or unsubstituted alkyl groups (having 1 to 8 carbon atoms, both linear and branched isomers), substituted or unsubstituted arylamino, or substituted or unsubstituted heteroaryl (having at least 5 carbon and heteroatoms in the ring) group. Alternatively, any two of R₁′, R₂′, and R₃′ groups may be joined together or with an adjacent aromatic ring to complete a 5- to 7-membered substituted or unsubstituted carbocyclic or heterocyclic ring.

For example, R₁′, R₂′, and R₃′ are independently hydrogen, a substituted or unsubstituted carbocyclic aryl group, and a substituted or unsubstituted heteroaryl group.

R₄′, R₅′, R₆′, and R₇′ each independently represents hydrogen, a substituted or unsubstituted alkyl group (having 1 to 10 carbon atoms), a substituted or unsubstituted cycloalkyl group (having from 4 to 6 carbon atoms in the ring), a substituted or unsubstituted aryl group (having at least 6 carbon atoms in the ring), or a substituted or unsubstituted heteroaryl group (having 5 to 10 carbon and heteroatoms in the ring).

Alternatively, R₄′ and R₅′ or R₆′ and R₇′ can be joined together to form a substituted or unsubstituted 5- to 9-membered heterocyclic ring, or R₄′, R₅′, R₆′, or R₇′ can be joined to the carbon atom of the adjacent aromatic ring at a position ortho to the position of attachment of the anilino nitrogen to form, along with the nitrogen to which they are attached, a substituted or unsubstituted 5- or 6-membered heterocyclic ring.

For example, R₄′, R₅′, R₆′, and R₇′ are independently a substituted or unsubstituted alkyl group, a substituted or unsubstituted cycloalkyl group, a substituted or unsubstituted aryl group, or R₄′ and R₅′ or R₆′ and R₇′ can be joined together to form a substituted or unsubstituted 5- to 7-membered heterocyclic ring. Also, they can be independently substituted or unsubstituted alkyl groups of 1 to 8 carbon atoms, substituted or unsubstituted phenyl groups, or R₄′ and R₅′ or R₆′ and R₇′ can be joined together to form a substituted or unsubstituted 5- to 7-membered heteroaryl group.

In the DYE I structure, s is 1, 2, or 3, Z₂ is a monovalent anion, X″ and Y″ are each independently R₁′ or the atoms necessary to complete a substituted or unsubstituted 5- to 7-membered fused carbocyclic or heterocyclic ring, and q and r are independently integers from 1 to 4.

For example, X″ and Y″ are independently hydrogen or the carbon and heteroatoms needed to provide a fused aryl or heteroaryl ring, Further details of such bis(aminoaryl)pentadiene IR dyes are provided, including representative IR dyes identified as DYE 1 through DYE 17, DYE 19, and DYE 20, in U.S. Pat. No. 6,623,908 (Zheng et al.).

Some useful infrared radiation absorbing dyes have a tetraaryl pentadiene chromophore. Such chromophore generally includes a pentadiene linking group having 5 carbon atoms in the chain, to which are attached two substituted or unsubstituted aryl groups at each end of the linking group. The pentadiene linking group can also be substituted with one or more substituents in place of the hydrogen atoms, or two or more hydrogen atoms can be replaced with atoms to form a ring in the linking group as long as there are alternative carbon-carbon single bonds and carbon-carbon double bonds in the chain.

Such IR-sensitive dyes can be represented by the following Structure DYE-II:

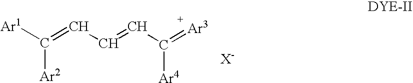

wherein Ar¹ through Ar⁴ are the same or different substituted or unsubstituted aryl groups having at least carbon atoms in the aromatic ring (such as phenyl, naphthyl, and anthryl, or other aromatic fused ring systems) wherein 1 to 3 of the aryl groups are substituted with the same or different tertiary amino group (such as in the 4-position of a phenyl group). Typically two of the aryl groups are substituted with the same or different tertiary amino group, and usually at different ends of the polymethine chain (that is, molecule). For example, Ar¹ or Ar² and Ar³ or Ar⁴ bear the tertiary amine groups. Representative amino groups include but are not limited to those substituted with substituted or unsubstituted alkyl groups having up to 10 carbon atoms or aryl groups such as dialkylamino groups (such as dimethylamino and diethylamino), diarylamino groups (such as diphenylamino), alkylarylamino groups (such as N-methylanilino), and heterocyclic groups such as pyrrolidino, morpholino, and piperidino groups. The tertiary amino group can form part of a fused ring such that one or more of Ar¹ through Ar⁴ can represent a julolidine group.

Besides the noted tertiary groups noted above, the aryl groups can be substituted with one or more substituted or unsubstituted alkyl groups having 1 to 10 carbon atoms, halo atoms (such as chloro or bromo), hydroxyl groups, thioether groups, and substituted or unsubstituted alkoxy groups having 1 to 10 carbon atoms. Substituents that contribute electron density to the conjugated system are useful. While they are not specifically shown in Structure (DYE-II), substituents or fused rings may also exist on (or as part of) the conjugated chain connecting the aryl groups.

In Structure (DYE-II), X⁻ is a suitable counterion that may be derived from a strong acid, and include such anions as ClO₄⁻, BF₄⁻, CF₃SO₃⁻, PF₆⁻, AsF₆⁻, SbF₆⁻, and perfluoroethylcyclohexylsulfonate. Other anions include boron-containing anions as described above (borates), methylbenzenesulfonate, benzenesulfonate, methanesulfonate, p-hydroxybenzenesulfonate, p-chlorobenzenesulfonate, and halides.

Two representative IR dyes defined by Structure (DYE-II) are defined as D1 and D2 in WO 98/07574 (Patel et al.). Still other useful IR-sensitive dyes are represented by the following Structure (DYE-III):

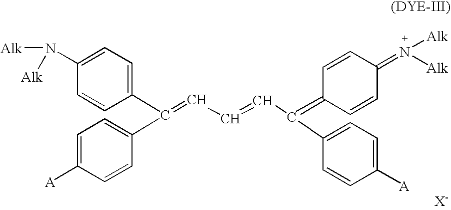

wherein “Alk” represents the same or different substituted or unsubstituted alkyl groups having 1 to 7 carbon atoms (such as substituted or unsubstituted methyl, ethyl, iso-propyl, t-butyl, n-hexyl, and benzyl), and “A” represents hydrogen or the same or different substituted or unsubstituted lower alkyl group having 1 to 3 carbon atoms (such as methyl, ethyl, n-propyl, and iso-propyl), or the same or different dialkylamino groups similar to those defined above for Structure (DYE-2), wherein such groups have the same or different alkyl groups. X⁻ is a suitable counterion as defined above for Structure (DYE-II).

Representative useful dyes of this type are described as Dyes 2, 3-A, 3-B, 3-C, 12, and 22 described in EP 438,123A2 (noted above)

Useful infrared radiation absorbing dyes can be obtained from a number of commercial sources including Showa Denko (Japan) or they can be prepared using known starting materials and procedures.

Still other useful infrared radiation absorbing compounds are copolymers can comprise covalently attached ammonium, sulfonium, phosphonium, or iodonium cations and infrared radiation absorbing cyanine anions that have two or four sulfonate or sulfate groups, or infrared radiation absorbing oxonol anions, as described for example in U.S. Pat. No. 7,049,046 (Tao et al.).

The infrared radiation absorbing compound (or sensitizer) can be present in the radiation-sensitive composition (or imageable layer) in an amount generally of at least 1% and up to and including 300% and typically at least 3 and up to and including 20%, based on total solids in the composition, that also corresponds to the total dry weight of the imageable layer. The particular amount needed for this purpose would be readily apparent to one skilled in the art, depending upon the specific compound used to provide the desired chromophore.

The imageable layer includes one or more polymeric binders. For example, useful polymeric binders include those having desired solubility in alkaline developers before exposure to imaging radiation. For example, useful polymeric binders can have pendant 1H-tetrazole groups as described in U.S. Ser. No. 11/949,810 (noted above).

Some other useful polymeric binders include polymeric resins that have one or more ethylenically unsaturated pendant groups (reactive vinyl groups) attached to the polymer backbone. Such reactive groups are capable of undergoing polymerizable or crosslinking in the presence of free radicals. The pendant groups can be directly attached to the polymer backbone with a carbon-carbon direct bond, or through a linking group (“X”) that is not particularly limited. The reactive vinyl groups may be substituted with at least one halogen atom, carboxy group, nitro group, cyano group, amide group, or alkyl, aryl, alkoxy, or aryloxy group, and particularly one or more alkyl groups. In some embodiments, the reactive vinyl group is attached to the polymer backbone through a phenylene group as described, for example, in U.S. Pat. No. 6,569,603 (Furukawa et al.). Other useful polymeric binders have vinyl groups in pendant groups that are described, for example in EP 1,182,033A1 (Fujimaki et al.) and U.S. Pat. No. 4,874,686 (Urabe et al.) and U.S. Pat. No. 7,041,416 (Wakata et al.) that are incorporated by reference, especially with respect to the general formulae (1) through (3) noted in EP 1,182,033A1.

Still other useful polymeric binders may be homogenous, that is, dissolved in the coating solvent, or may exist as discrete particles. Such secondary polymeric binders include but are not limited to, (meth)acrylic acid and acid ester resins [such as (meth)acrylates], polyvinyl acetals, phenolic resins, polymers derived from styrene, N-substituted cyclic imides or maleic anhydrides, such as those described in EP 1,182,033 (Fujimaki et al.) and U.S. Pat. No. 6,309,792 (Hauck et al.), U.S. Pat. No. 6,352,812 (Shimazu et al.), U.S. Pat. No. 6,569,603 (Furukawa et al.), and U.S. Pat. No. 6,893,797 (Munnelly et al.). Also useful are the vinyl carbazole polymers described in U.S. Pat. No. 7,175,949 (Tao et al.). Copolymers of polyethylene glycol methacrylate/acrylonitrile/styrene in particulate form, dissolved copolymers derived from carboxyphenyl methacrylamide/acrylonitrile/-methacrylamide/N-phenyl maleimide, copolymers derived from polyethylene glycol methacrylate/acrylonitrile/vinylcarbazole/styrene/methylacrylic acid, copolymers derived from N-phenyl maleimide/methacrylamide/methacrylic acid, copolymers derived from urethane-acrylic intermediate A (the reaction product of p-toluene sulfonyl isocyanate and hydroxyl ethyl methacrylate)/acrylonitrile/N-phenyl maleimide, and copolymers derived from N-methoxymethyl methacrylamide/methacrylic acid/acrylonitrile/n-phenylmaleimide are useful.

Other useful polymeric binders are particulate poly(urethane-acrylic)hybrids that are distributed (usually uniformly) throughout the imageable layer. Each of these hybrids has a molecular weight of from about 50,000 to about 500,000 and the particles have an average particle size of from about 10 to about 10,000 nm (typically from about 30 to about 500 nm and or from about 30 to about 150 nm). These hybrids can be either “aromatic” or “aliphatic” in nature depending upon the specific reactants used in their manufacture. Blends of particles of two or more poly(urethane-acrylic) hybrids can also be used. For example, a blend of Hybridur® 570 polymer dispersion with Hybridur® 870 polymer dispersion could be used.

Some poly(urethane-acrylic) hybrids are commercially available in dispersions from Air Products and Chemicals, Inc. (Allentown, Pa.), for example, as the Hybridur® 540, 560, 570, 580, 870, 878, 880 polymer dispersions of poly(urethane-acrylic) hybrid particles. These dispersions generally include at least 30% solids of the poly(urethane-acrylic) hybrid particles in a suitable aqueous medium that may also include commercial surfactants, anti-foaming agents, dispersing agents, anti-corrosive agents, and optionally pigments and water-miscible organic solvents. Further details about each commercial Hybridur® polymer dispersion can be obtained by visiting the Air Products and Chemicals, Inc. website.

The one or more polymeric binders are generally present in the radiation-sensitive composition in an amount of from about 10 to about 70%, based on the total imageable layer dry weight. These binders may comprise up to 100% of the dry weight of all polymeric binders (primary polymeric binders plus any secondary polymeric binders).

As described above, the radiation-sensitive composition and imageable layer used in the imageable element contains one or more adhesion promoters, each of which has an ethylenically unsaturated, substituted or unsubstituted carbon-carbon double bond that is directly or indirectly connected to a substituted or unsubstituted alkoxysilyl or hydroxysilyl group. By definition a “silyl group” is a radical of silane. By “directly connected”, we mean that a carbon-silicon bond connects the two groups. In many embodiments, a suitable organic linking group having 1 to 8 carbon, sulfur, nitrogen, oxygen, or sulfur atoms in the substituted or unsubstituted linking chain, connects the two groups. These compounds generally have a molecular weight of at least 120 and typically of at least 145 and up to and including 1000.

For example, the adhesion promoter can be represented by the following Structure (I):

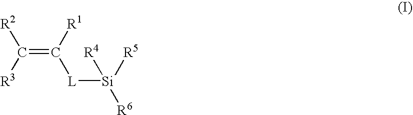

wherein R¹ to R³ are independently hydrogen or halogen (such as chloro or bromo) or substituted or unsubstituted alkyl groups (for example, having 1 to 6 carbon atoms, and can be linear or branched). For example, R¹ to R³ can be independently hydrogen, chloro, methyl, or ethyl, and in some embodiments, they are independently hydrogen or methyl groups.

R⁴ to R⁶ are independently hydrogen or halogen (such as chloro or bromo), hydroxy, substituted or unsubstituted alkyl groups having 1 to 8 carbon atoms (such as methyl, ethyl, n-propyl, isopropyl, t-butyl, benzyl, and octyl groups), substituted or unsubstituted alkoxy groups having 1 to 8 carbon atoms (such as methoxy, ethoxy, t-butoxy, benzyloxy, and octyloxy groups), or substituted or unsubstituted carbocyclic aryl groups having 6 or 10 carbon atoms in the aromatic ring (such as phenyl, naphthyl, and 4-methylphenyl groups). At least one of R⁴ to R⁶ is a hydroxy or substituted or unsubstituted alkoxy group (such as a methoxy or ethoxy group).

L is a direct Si—C bond or a divalent linking group, such as a divalent organic linking group that may be substituted (have one or more side chains) and includes 1 to 8 carbon, sulfur, nitrogen, oxygen, or sulfur atoms in the linking chain. For example, L can be a linking group comprising one or more oxy, thio, substituted or unsubstituted alkylene (having 1 to 8 carbon atoms), substituted or unsubstituted alkenylene (having 2 to 8 carbon atoms), substituted or unsubstituted arylene (having 6 or 10 carbon atoms in the carbocyclic ring), sulfonyl, carbonyl, substituted or unsubstituted amino (primary, secondary, or tertiary), —CH(OH)—, —C(═O)—, —OC(═O)—, substituted or unsubstituted heterocyclylene groups (having 5 to 10 carbon and heteroatoms in the ring), or any combination of two or more thereof. In some embodiments, L is a direct Si—C bond or a —C(═O)—O—(CH₂)ₙ— linking group wherein n is 1 to 6.

In some embodiments, R₁ to R³ are independently hydrogen or methyl groups, and R⁴ to R⁶ are independently hydrogen or hydroxy, alkyl, alkoxy, or aryl groups provided that at least two of R⁴ to R⁶ are hydroxy, methoxy, or ethoxy groups.

In still other embodiments, R¹ to R³ are independently hydrogen or methyl group, R⁴ to R⁶ are independently hydrogen or hydroxy, methyl, ethyl, phenyl, methoxy, or ethoxy groups provided that at least two of R⁴ to R⁶ are methoxy or ethoxy groups.

Examples of useful adhesion promoters are vinyltrimethoxysilane, vinylmethyldimethoxysilane, vinyltriethoxysilane, vinyltris(2-methoxyethoxy)silane, vinyltriacetyloxysilane, 3-acryloxypropyl-trimethoxysilane, 3-methacryloxypropyltrimethoxysilane, 3-methacryloxypropylmethyldimethoxysilane.

The one or more adhesion promoters are present in the imageable layer in an amount of at least 0.1 weight % and up to and including 12 weight %, and typically of at least 0.2 weight % and up to and including 8 weight %. Optimum amounts can be readily determined by a skilled artisan with routine experimentation to determined with adhesion promoter and how much is best with a given radiation-sensitive composition.

The adhesion promoters can be obtained from a number of commercial sources such as Sigma-Aldrich Chemical Company and TCI America.

The imageable layer can further comprise one or more phosphate (meth)acrylates, each of which has a molecular weight generally greater than 200 and typically at least 300 and up to and including 1000. By “phosphate (meth)acrylate” we also mean to include “phosphate methacrylates” and other derivatives having substituents on the vinyl group in the acrylate moiety.

Each phosphate moiety is typically connected to an acrylate moiety by an aliphatic chain [that is, an -(aliphatic-O)— chain] such as an alkyleneoxy chain [that is an -(alkylene-O)ₘ— chain] composed of at least one alkyleneoxy unit, in which the alkylene moiety has 2 to 6 carbon atoms and can be either linear or branched and m is 1 to 10. For example, the alkyleneoxy chain can comprise ethyleneoxy units, and m is from 2 to 8 or m is from 3 to 6. The alkyleneoxy chains in a specific compound can be the same or different in length and have the same or different alkylene group.

Useful phosphate(meth)acrylates can be represented by the following Structure (III):

P(═O)(OM)ₙ(OR)₃₋ₙ (IlI)

wherein n is 1 or 2, M is hydrogen or a monovalent cation (such as an alkali metal ion, ammonium cations including cations that include one to four hydrogen atoms). For example, useful M cations include but are not limited to sodium, potassium, —NH₄, —NH(CH₂CH₂OH)₃, and —NH₃(CH₂CH₂OH). When n is 2, the M groups are the same or different. The compounds wherein M is hydrogen are particularly useful.

The R groups are independently the same or different groups represented by the following Structure (IV):

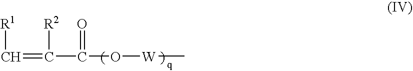

wherein R¹ and R² are independently hydrogen, or a halo (such as chloro or bromo) or substituted or unsubstituted alkyl group having 1 to 6 carbon atoms (such as methyl, chloromethyl, methoxymethyl, ethyl, isopropyl, and t-butyl groups). In many embodiments, one or both of R¹ and R² are hydrogen or methyl, and in some embodiments, R¹ is hydrogen and R² is methyl).

W is an aliphatic group having at least 2 carbon or oxygen atoms, or combination of carbon and oxygen atoms, in the chain, and q is 1 to 10. Thus, W can include one or more alkylene groups having 1 to 8 carbon atoms that are interrupted with one or more oxygen atoms (oxy groups), carbonyl, oxycarbonyl, or carbonyl oxy groups. For example, one such aliphatic group is an alkylenecarbonyloxyalkylene group. Useful alkylene groups included in the aliphatic groups have 2 to 5 carbon atoms and can be branched or linear in form.

The R groups can also independently be the same or different groups represented by the following Structure (V):

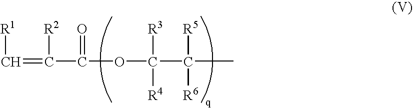

wherein R¹, R², and q are as defined above and R³ through R⁶ of Structure (V) are independently hydrogen or a substituted or unsubstituted alkyl group having 1 to 6 carbon atoms (such as methyl, methoxymethyl), ethyl, chloromethyl, hydroxymethyl, ethyl, iso-propyl, n-butyl, t-butyl, and n-pentyl groups). Typically, R³ through R⁶ are independently hydrogen or methyl, and in most embodiments, all are hydrogen.

In Structures IV and V, q is 1 to 10, or from 2 to 8, for example from 3 to 6.

Representative phosphate (meth)acrylates useful in this invention include but are not limited to, ethylene glycol methacrylate phosphate (available from Aldrich Chemical Co.), a phosphate of 2-hydroxyethyl methacrylate that is available as Kayamer PM-2 from Nippon Kayaku (Japan) that is shown below, a phosphate of a di(caprolactone modified 2-hydroxyethyl methacrylate) that is available as Kayamer PM-21 (Nippon Kayaku, Japan) that is also shown below, and a polyethylene glycol methacrylate phosphate with 4-5 ethoxy groups that is available as Phosmer PE from Uni-Chemical Co., Ltd. (Japan) that is also shown below. Still other useful compounds of this type are commercially available from Sartomer Company, Inc. (Exton, Pa.) as Sartomer SR 705, SR 9011, SR 9012, CD 9050, CD 9051, and CD 9053. Other useful nonionic phosphate acrylates are also shown below.

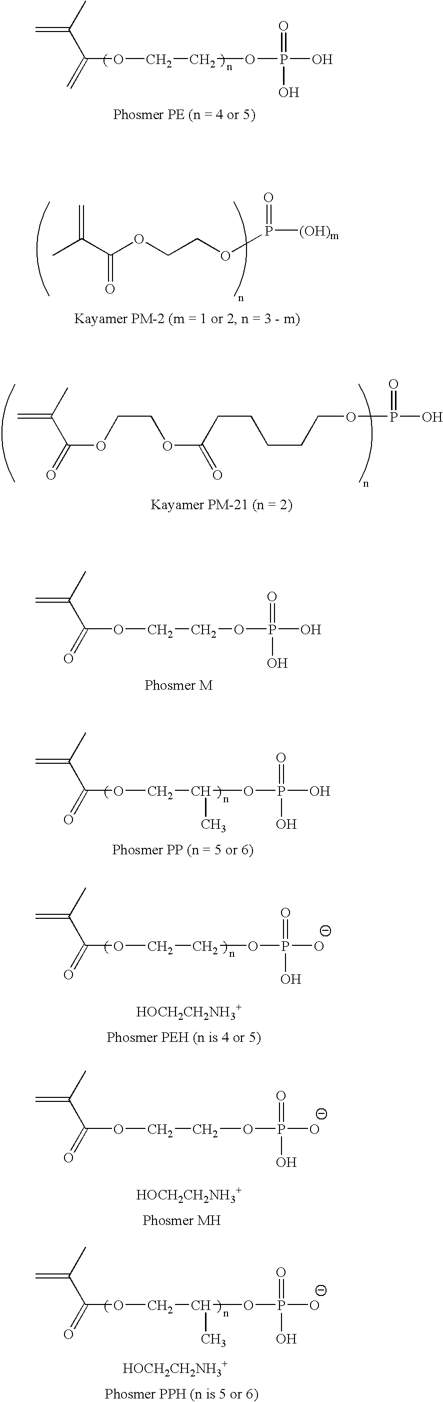

The phosphate acrylate can be present in the imageable layer in an amount of at least 0.5 and up to and including 20% and typically at least 0.9 and up to and including 10%, by weight of the total solids.

The imageable layer can also include a “primary additive” that is a poly(alkylene glycol) or an ether or ester thereof that has a molecular weight of at least 200 and up to and including 4000. This primary additive is present in an amount of at least 2 and up to and including 50 weight %, based on the total dry weight of the imageable layer. Useful primary additives include, but are not limited to, one or more of polyethylene glycol, polypropylene glycol, polyethylene glycol methyl ether, polyethylene glycol dimethyl ether, polyethylene glycol monoethyl ether, polyethylene glycol diacrylate, ethoxylated bisphenol A di(meth)acrylate, and polyethylene glycol mono methacrylate. Also useful are SR9036 (ethoxylated (30) bisphenol A dimethacrylate), CD9038 (ethoxylated (30) bisphenol A diacrylate), and SR494 (ethoxylated (5) pentaerythritol tetraacrylate), and similar compounds all of which that can be obtained from Sartomer Company, Inc. In some embodiments, the primary additive may be “non-reactive” meaning that it does not contain polymerizable vinyl groups.

The imageable layer can also include a “secondary additive” that is a poly(vinyl alcohol), a poly(vinyl pyrrolidone), poly(vinyl imidazole), or polyester in an amount of up to and including 20 weight % based on the total dry weight of the imageable layer.

The imageable layer can also include a variety of optional compounds including but not limited to, dispersing agents, humectants, biocides, plasticizers, surfactants for coatability or other properties, viscosity builders, dyes or colorants to allow visualization of the written image (such as crystal violet, methyl violet, ethyl violet, Victoria blue, malachite green, and brilliant green), pH adjusters, drying agents, defoamers, preservatives, antioxidants, development aids, rheology modifiers or combinations thereof, or any other addenda commonly used in the lithographic art, in conventional amounts. Useful viscosity builders include hydroxypropyl cellulose, hydroxyethyl cellulose, carboxymethyl cellulose, and poly(vinyl pyrrolidones).

### Imageable Elements

The imageable elements can be formed by suitable application of an infrared radiation-sensitive composition as described above to a suitable substrate to form an imageable layer. This substrate can be treated or coated in various ways as described below prior to application of the radiation-sensitive composition to improve hydrophilicity. Typically, there is only a single imageable layer comprising the radiation-sensitive composition that is directly applied to the substrate without any intermediate layer such as those described in EP Patent Publications described above in the Background of the Invention. If the substrate has been treated to provide improved adhesion or hydrophilicity, the applied imageable layer is disposed thereon but these treatments are not considered “intermediate layers” for the purpose of this invention.

The element does not include what is conventionally known as an overcoat (also known as an “oxygen impermeable topcoat” or “oxygen barrier layer”) disposed over the imageable layer. Thus, the imageable layer is the outermost layer of the element.

The substrate generally has a hydrophilic surface, or at least a surface that is more hydrophilic than the applied imageable layer on the imaging side. The substrate comprises a support that can be composed of any material that is conventionally used to prepare imageable elements such as lithographic printing plates. It is usually in the form of a sheet, film, or foil (or web), and is strong, stable, and flexible and resistant to dimensional change under conditions of use so that color records will register a full-color image. Typically, the support can be any self-supporting material including polymeric films (such as polyester, polyethylene, polycarbonate, cellulose ester polymer, and polystyrene films), glass, ceramics, metal sheets or foils, or stiff papers (including resin-coated and metallized papers), or a lamination of any of these materials (such as a lamination of an aluminum foil onto a polyester film). Metal supports include sheets or foils of aluminum, copper, zinc, titanium, and alloys thereof.

One useful substrate is composed of an aluminum support that may be treated using techniques known in the art, including roughening of some type by physical (mechanical) graining, electrochemical graining, or chemical graining, usually followed by acid anodizing. The aluminum support can be roughened by physical or electrochemical graining and then anodized using phosphoric or sulfuric acid and conventional procedures. A useful hydrophilic lithographic substrate is an electrochemically grained and sulfuric acid anodized aluminum support that provides a hydrophilic surface for lithographic printing.

Sulfuric acid anodization of the aluminum support generally provides an oxide weight (coverage) on the surface of from about 1.5 to about 5 g/m² and more typically from about 3 to about 4.3 g/m². Phosphoric acid anodization generally provides an oxide weight on the surface of from about 1.5 to about 5 g/m² and more typically from about 1 to about 3 g/m². When sulfuric acid is used for anodization, higher oxide weight (at least 3 g/m²) may provide longer press life.

The aluminum support may also be treated with, for example, a silicate, dextrine, calcium zirconium fluoride, hexafluorosilicic acid, poly(vinyl phosphonic acid) (PVPA), vinyl phosphonic acid copolymer, poly[(meth)acrylic acid], or acrylic acid copolymer to increase hydrophilicity. Still further, the aluminum support may be treated with a phosphate solution that may further contain an inorganic fluoride (PF). The aluminum support can be electrochemically-grained, sulfuric acid-anodized, and treated with PVPA or PF using known procedures to improve surface hydrophilicity.

The thickness of the substrate can be varied but should be sufficient to sustain the wear from printing and thin enough to wrap around a printing form. Useful embodiments include a treated aluminum foil having a thickness of at least 100 μm and up to and including 700 μm.

The backside (non-imaging side) of the substrate may be coated with antistatic agents and/or slipping layers or a matte layer to improve handling and “feel” of the imageable element.

The substrate can also be a cylindrical surface having the imageable layer thereon, and thus be an integral part of the printing press. The use of such imaging cylinders is described for example in U.S. Pat. No. 5,713,287 (Gelbart).

An infrared radiation-sensitive composition containing the components described above can be applied to the substrate as a solution or dispersion in a coating liquid using any suitable equipment and procedure, such as spin coating, knife coating, gravure coating, die coating, slot coating, bar coating, wire rod coating, roller coating, or extrusion hopper coating. The composition can also be applied by spraying onto a suitable support (such as an on-press printing cylinder).

Illustrative of such manufacturing methods is mixing the free radically polymerizable component, polymeric binder(s), initiator composition, IR radiation absorbing compound, adhesion promoter, and any other components of the infrared radiation-sensitive composition in a suitable coating solvent including water, organic solvents [such as glycol ethers including 1-methoxypropan-2-ol, methyl ethyl ketone(2-butanone), methanol, ethanol, 1-methoxy-2-propanol, iso-propyl alcohol, acetone, γ-butyrolactone, n-propanol, tetrahydrofuran, and others readily known in the art, as well as mixtures thereof], or mixtures thereof, applying the resulting solution to a substrate, and removing the solvent(s) by evaporation under suitable drying conditions. Some representative coating solvents and imageable layer formulations are described in the Examples below. After proper drying, the coating weight of the imageable layer is generally at least 0.1 and up to and including 5 g/m² or at least 0.5 and up to and including 3.5 g/m². Any particulate polymeric binders present in the imageable layer may partially coalesce or be deformed during the drying operation.

Once the imageable layer has been applied and dried on the substrate, the imageable element can be enclosed in water-impermeable material that substantially inhibits the transfer of moisture to and from the imageable element.

By “enclosed”, we mean that the imageable element is wrapped, encased, enveloped, or contained in a manner such that both upper and lower surfaces and all edges are within the water-impermeable sheet material. Thus, none of the imageable element is exposed to the environment once it is enclosed.

Useful water-impermeable sheet materials include but are not limited to, plastic films, metal foils, and waterproof papers that are usually in sheet-form and sufficiently flexible to conform closely to the shape of the imageable element (or stack thereof as noted below) including an irregularities in the surfaces. Typically, the water-impermeable sheet material is in close contact with the imageable element (or stack thereof). In addition, this material can be sufficiently tight or is sealed, or both, so as to provide a sufficient barrier to the movement or transfer of moisture to or from the imageable element. Useful water-impermeable materials include plastic films such as films composed of low density polyethylene, polypropylene, and poly(ethylene terephthalate), metallic foils such as foils of aluminum, and waterproof papers such as papers coated with polymeric resins or laminated with metal foils (such as paper backed aluminum foil). In addition, the edges of the water-impermeable sheet materials can be folded over the edges of the imageable elements and sealed with suitable sealing means such as sealing tape and adhesives.

The transfer of moisture from and to the imageable element is “substantially inhibited”, meaning that over a 24-hour period, the imageable element neither loses nor gains no more than 0.01 g of water per m². The imageable element (or stack) can be enclosed or wrapped while under vacuum to remove most of the air and moisture. In addition to or instead of vacuum, the environment (for example, humidity) of the imageable element can be controlled (for example to a relative humidity of less than 20%), and a desiccant can be associated with the imageable element (or stack).

For example, the imageable element can be enclosed with the water-impermeable sheet material as part of a stack of imageable elements, which stack contains at least 5 imageable elements and more generally at least 100 or at least 500 imageable elements that are enclosed together. It may be desirable to use “dummy”, “reject”, or non-photosensitive elements at the top and bottom of the stack to improve the wrapping. Alternatively, the imageable element can be enclosed in the form of a coil that can be cut into individual elements at a later time. Generally, such a coil has at least 1000 m² of imageable surface, and commonly at least 3000 m² of imageable surface.

Adjacent imageable elements in the stacks or adjacent spirals of the coil may be separated by interleaving material, for example interleaving paper or tissue (“interleaf paper”) that may be sized or coated with waxes or resin (such as polyethylene) or inorganic particles. Many useful interleaving materials are commercially available. They generally have a moisture content of less than 8% or typically less than 6%.

### Imaging Conditions

During use, the imageable element is exposed to a suitable source of imaging or exposing radiation such as near-infrared or infrared radiation, depending upon the infrared radiation absorbing compound present in the radiation-sensitive composition, at a wavelength of from about 700 to about 1500 nm. For example, imaging can be carried out using imaging or exposing radiation, such as from an infrared laser at a wavelength of at least 750 nm and up to and including about 1400 nm and typically at least 700 nm and up to and including 1200 nm. Imaging can be carried out using imaging radiation at multiple wavelengths at the same time if desired.

The laser used to expose the imageable element is usually a diode laser, because of the reliability and low maintenance of diode laser systems, but other lasers such as gas or solid-state lasers may also be used. The combination of power, intensity and exposure time for laser imaging would be readily apparent to one skilled in the art. Presently, high performance lasers or laser diodes used in commercially available imagesetters emit infrared radiation at a wavelength of at least 800 nm and up to and including 850 nm or at least 1060 and up to and including 1120 nm.

The imaging apparatus can function solely as a platesetter or it can be incorporated directly into a lithographic printing press. In the latter case, printing may commence immediately after imaging and development, thereby reducing press set-up time considerably. The imaging apparatus can be configured as a flatbed recorder or as a drum recorder, with the imageable member mounted to the interior or exterior cylindrical surface of the drum. An example of an useful imaging apparatus is available as models of Kodak Trendsetter® platesetters available from Eastman Kodak Company (Burnaby, British Columbia, Canada) that contain laser diodes that emit near infrared radiation at a wavelength of about 830 nm. Other suitable imaging sources include the Crescent 42T Platesetter that operates at a wavelength of 1064 nm (available from Gerber Scientific, Chicago, Ill.) and the Screen PlateRite 4300 series or 8600 series platesetter (available from Screen, Chicago, Ill.). Additional useful sources of radiation include direct imaging presses that can be used to image an element while it is attached to the printing plate cylinder. An example of a suitable direct imaging printing press includes the Heidelberg SM74-DI press (available from Heidelberg, Dayton, Ohio).

Imaging with infrared radiation can be carried out generally at imaging energies of at least 30 mJ/cm² and up to and including 500 mJ/cm², and typically at least 50 and up to and including 300 mJ/cm² depending upon the sensitivity of the imageable layer.

### Development and Printing

With or without a post-exposure baking step after imaging and before development, the imaged elements can be developed “off-press” using an alkaline developer as described herein.

The developer composition commonly includes surfactants, chelating agents (such as salts of ethylenediaminetetraacetic acid), organic solvents (such as benzyl alcohol), and alkaline components (such as inorganic metasilicates, organic metasilicates, hydroxides, and bicarbonates). The pH of the developer is generally from about 4 to about 14. The imaged elements are generally developed using conventional processing conditions. Aqueous alkaline developers and organic solvent-containing alkaline developers can be used.

Organic solvent-containing alkaline developers are generally single-phase solutions of one or more organic solvents that are miscible with water, and generally have a pH below 12. In general, these developers have a pH of at least 6. Typically, the pH is 10 or less and more typically it is from about 6.5 to about 9.5. Useful organic solvents include the reaction products of phenol with ethylene oxide and propylene oxide [such as ethylene glycol phenyl ether (phenoxyethanol)], benzyl alcohol, esters of ethylene glycol and of propylene glycol with acids having 6 or less carbon atoms, and ethers of ethylene glycol, diethylene glycol, and of propylene glycol with alkyl groups having 6 or less carbon atoms, such as 2-ethylethanol and 2-butoxyethanol.

The noted organic solvents are present in the developer in an amount of from about 0.5 to about 15 weight % (based on total developer weight), but typically in an amount of at least 2% solids and up to and including 10% solids (based on total developer weight).

The developers can also comprise a) an amphoteric surfactant comprising a nitrogen-containing heterocycle, b) an amphoteric surfactant having two or more nitrogen atoms, or c) an amphoteric surfactant of a) and an amphoteric surfactant of b). For example, the amphoteric surfactant can be type a) and comprise two basic nitrogen atoms in the heterocyclic ring. In some embodiments, the amphoteric surfactant comprises both nitrogen atoms and carboxy groups wherein the number of nitrogen atoms is greater than the number of carboxy groups. Some amphoteric surfactants have a carboxylate (usually through a linking group) attached to a nitrogen-containing heterocycle. One such useful amphoteric surfactant is represented as follows:

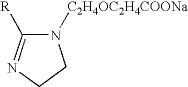

wherein R is a substituted or unsubstituted alkyl group having 1 to 20 carbon atoms and preferably from about 3 to 12 carbon atoms. Commercial examples of such amphoteric surfactants include but are not limited to, Crodateric CyNa50 (available from Croda, Edison, N.J.) that is a capryloamphoproprionate, and ALKAWET.RTM.LF (available from Lonza, Allendale, N.J.).

The amphoteric surfactant can be present in an amount of at least 2 weight % (typically at least 4 weight %), and up to 10 weight %, in the developer (based on total developer weight).

The developer can further comprise a benzene or naphthalene sulfonate surfactant (or both) in an amount of at least 5 weight % (typically at least 6.5 weight % solids and up to 15 weight %). Commercial examples (or sources) of such surfactants include but are not limited to, Naxonate® 4L and Naxonate® 4ST (from Nease Corporation, Blue Ash, Ohio) containing benzene sulfonates and Naxan® ABL (from Nease Corporation), Geowet WL (from GEO Specialty Chemicals, Lafayette, Ind.), and Petro AA (from Monson Corporation, Leominster, Mass.) for naphthalene sulfonates.

It is desirable that the weight ratio of all of the surfactants (total of amphoteric and benzene or naphthalene sulfonate surfactants) to organic solvent(s) such as benzyl alcohol, in the developer be at least 2.5:1 and typically at least 3:1.

Representative organic solvent-containing alkaline developers include ND-1 Developer, 955 Developer, 956 Developer, 989 Developer, Developer 980, and 956 Developer (available from Eastman Kodak Company), HDN-1 Developer and LP-DS Developer (available from Fuji Photo), and EN 232 Developer and PL10 Developer (available from Agfa).

Useful aqueous alkaline developers generally have a pH of at least 7 and preferably of at least 11 and up to 13.5. Such developers include but are note limited to, 3000 Developer, 9000 Developer, GoldStar® Developer, GoldStar® Plus Developer, GoldStar® Premium Developer, GREENSTAR Developer, ThermalPro Developer, PROTHERM Developer, MX1813 Developer, and MX1710 Developer (all available from Eastman Kodak Company), as well as Fuji HDP7 Developer (Fuji Photo), and Energy CTP Developer (Agfa). These compositions also generally include surfactants, chelating agents (such as salts of ethylenediaminetetraacetic acid), and alkaline components (such as inorganic metasilicates, organic metasilicates, hydroxides, and bicarbonates).

Such alkaline developers can also include one or more “coating-attack suppressing agents” that are developer-soluble compounds that suppress developer attack of the outer layer. “Developer-soluble” means that enough of the agent(s) will dissolve in the developer to suppress attack by the developer. Mixtures of these compounds can be used. Typically, the coating-attack suppressing agents are developer-soluble polyethoxylated, polypropoxylated, or polybutoxylated compounds that include recurring —(CH₂—CHRₐ—O—)— units in which Rₐ is hydrogen or a methyl or ethyl group. Each agent can have the same or different recurring units (in a random or block fashion). Representative compounds of this type include but are not limited to, polyglycols and polycondensation products having the noted recurring units. Examples of such compounds and representative sources, tradenames, or methods of preparing are described for example in U.S. Pat. No. 6,649,324 (Fiebag et al.) that is incorporated herein by reference.

Generally, a developer is applied to the imaged element by rubbing or wiping the outer layer with an applicator containing the developer. Alternatively, the imaged element can be brushed with the developer or the developer may be applied by spraying the outer layer with sufficient force to remove the exposed regions. Still again, the imaged element can be immersed in the developer. In all instances, a developed image is produced in a lithographic printing plate having excellent resistance to press room chemicals. These development processes can be carried out in suitable developing processors or equipment using standard residence times and recirculation and replenishment rates.

Following off-press development, a postbake operation can be carried out, with or without a blanket or floodwise exposure to UV or visible radiation. Alternatively, a blanket UV or visible radiation exposure can be carried out, without a postbake operation.

Printing can be carried out by applying a lithographic printing ink and fountain solution to the printing surface of the imaged and developed element. The fountain solution is taken up by the non-imaged regions, that is, the surface of the hydrophilic substrate revealed by the imaging and development steps, and the ink is taken up by the imaged (non-removed) regions of the imaged layer. The ink is then transferred to a suitable receiving material (such as cloth, paper, metal, glass, or plastic) to provide a desired impression of the image thereon. If desired, an intermediate “blanket” roller can be used to transfer the ink from the imaged member to the receiving material. The imaged members can be cleaned between impressions, if desired, using conventional cleaning means.

The following examples are provided to illustrate the practice of the invention but are by no means intended to limit the invention in any manner.

### EXAMPLES

Unless otherwise noted below, the chemical components used in the Examples can be obtained from one or more commercial courses such as Aldrich Chemical Company (Milwaukee, Wis.).

The components and materials used in the examples and analytical methods used in evaluation were as follows:

Byk® 307 is a polyethoxylated dimethyl polysiloxane copolymer that is available from Byk Chemie (Wallingford, Conn.) in a 10 wt. % 1-methoxy-2-propanol solution.

DMAC represents N,N′-dimethylacetamide.

Graft polymer 1 is a polymer dispersion containing 20 wt. % styrene, 70 wt. % acrylonitrile, and 10 wt. % polyethylene glycol methyl ether methacrylate, 24% in propanol/water (80/20).

Initiator A is bis(4-t-butylphenyl)iodonium tetraphenylborate.

IRT is an IR Dye that was obtained from Showa Denko (Japan).

MEK represents methyl ethyl ketone.

Oligomer A is a dipentaerythritol hexaacrylate that was obtained from Kowa American (New York, N.Y.).

PGME represents 1-methoxy-2-propanol (also known as Dowanol® PM).

Pigment A is a 27% solids dispersion of 7.7 parts of a polyvinyl acetal derived from poly(vinyl alcohol) acetalized with acetaldehyde, butyraldehyde, and 4-formylbenzoic acid, 76.9 parts of Irgalith Blue GLVO (Cu-phthalocyanine C.I. Pigment Blue 15:4) and 15.4 parts of Disperbyk® 167 dispersant (Byk Chemie) in 1-methoxy-2-propanol.

Sartomer 399 is dipentaerythritol pentaacrylate that was obtained from Sartomer Company, Inc. (Exton, Pa.).

Sipomer PAM100 is an ethylene glycol methacrylate phosphate with 4-5 ethylene glycol units that was obtained from Rhodia Inc. (Cranbury, N.J.).

TMSPMA is a 3-trimethoxysilylpropyl methacrylate.

955 Developer is a benzyl alcohol-containing alkaline “negative” developer that is available from Eastman Kodak Company (Rochester, N.Y.).

### Synthetic Preparation of Polymer A (Invention):

AIBN [2,2′-azobis(iso-butyronitrile), Vazo-64, 1.6 g], methyl methacrylate (12 g), acrylonitrile (25 g), N-vinyl carbazole (18 g, from Polymer Dajac), methacrylic acid (25 g), and DMAC (320 g) were placed in a 1000-ml 3-necked flask, equipped with magnetic stirring, temperature controller, and N₂ inlet. The reaction mixture was heated to 75° C. and stirred under N₂ protection overnight (about 16 hours). The % N.V. was measured with about 20%.

To above reaction mixture (after nitrogen protection was removed), potassium hydroxide (11.8 g) in water (40 g) was slowly added and a viscous liquid was formed. After stirring the mixture for 20 minutes, allyl bromide (25.5 g) was added and the mixture was stirred at 55° C. for 3 hours. Concentrated (36%) hydrochloric acid (23 g) in DMAC (50 g) was added to the flask and the reaction mixture was stirred for another 3 hours. The resulting reaction mixture was then slowly dropped into a mixture of 12 liters of ice water with 20 g of concentrated hydrochloric acid while stirring. The resulting precipitate was washed with 2000 ml of propanol, followed by washing with 3000 ml of water. A fine white powder was obtained after filtration. The powder was dried at room temperature overnight and then at 50° C. for 3 hours to obtain 81 g of polymer solid.

### Invention Example 1

### Single-Layer Negative-Working Imageable Element with TMSPMA

An imageable layer formulation was prepared by dissolving Polymer A (0.84 kg), Oligomer A (0.73 kg), IRT Dye (0.11 kg), Graft Polymer 1 (2.38 kg), SR-399 (1.83 kg, 40% in MEK), Pigment 951 (1.05 kg), Sipomer PAM100 (0.07 kg), Byk® 307 (0.35 kg), TMSPMA (0.07 kg), and Initiator A (0.24 kg) in PGME (30.88 kg), water (2.83 kg) and MEK (18.7 kg). An electrochemically-grained and sulfuric acid-anodized aluminum substrate that had been post-treated with poly(vinyl phosphonic acid) was coated with the imageable layer formulation at a dry coating weight of about 1.2 g/m².

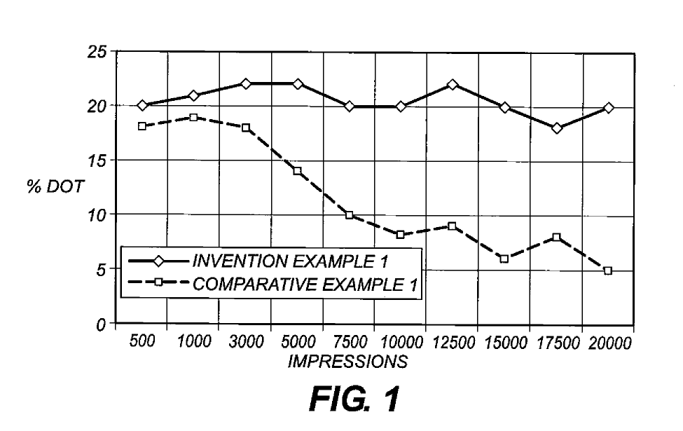

A sample of the resulting imageable element was imagewise exposed to a 830 nm IR laser at a drum speed of 250 rpm and varying power from 4 to 16 watts on a Kodak Trendsetter 3244x imagesetter, and was developed in an NE 34 processor (from Eastman Kodak Company) containing 955 Developer at 23° C. The minimum energy to achieve a stable solid density and clean background was about 65 mJ/cm². Another sample of the imageable element was incubated at 48° C. for 5 days and then imaged and developed in a similar fashion. It showed similar digital speed and resulting clean backgrounds. Still another sample of the resulting imageable element was exposed at 110 mJ/cm² on the Kodak Trendsetter 3244x imagesetter and was developed in an NE34 processor containing 955 Developer at 5 ft/minute (1.5 m/minute). The resulting developed element was then mounted onto a Miehle sheet-fed press using a wear ink containing 1.5% calcium carbonate to produce from about 20,000 good impressions. The % of AM (amplitude modulation) screening at 200 lines per inch (508 lines per cm) was recorded by reading the 10% AM dots on press (that is, measurement was made on paper/press-sheet) as a function of the number of the impression (See FIG. 1).

### Comparative Example 1

An imageable layer coating formulation outside of this invention was prepared by dissolving Polymer A (0.42 kg), Oligomer A (0.37 kg), Graft Polymer 1 (1.19 kg), SR-399 (0.92 kg, 40% in MEK), Initiator A (0.12 kg), IRT Dye (0.06 kg), Pigment 951 (0.52 kg), Sipomer PAM-100 (0.04 kg), and a 10% Byk® 307 solution (0.18 g) in PGME (15.44 kg), water (1.42 kg) and MEK (9.35 g). This formulation was coated onto an electrochemically-grained and sulfuric acid anodized aluminum substrate that had been post-treated with poly(vinyl phosphoric acid) to provide a dry coating weight of about 1.2 g/m².

A sample of the resulting imageable element was imagewise exposed to a 830 nm IR laser at a drum speed of 250 rpm and varying power from 4 to 16 watts on a Kodak Trendsetter 3244x imagesetter and was developed in an NE 34 processor (from Kodak) containing 955 Developer at 23° C. The minimum energy to achieve a stable solid density and clean background was about 65 mJ/cm². Another sample of the imageable element was incubated at 48° C. for 5 days and then imaged and developed in a similar fashion. It showed similar digital speed and resulting clean backgrounds. Still another sample of the resulting imageable element was exposed at 110 mJ/cm² on the Kodak Trendsetter 3244x imagesetter and was developed in an NE34 processor containing 955 Developer at 5 ft/minute (1.5 m/minute). The resulting developed element was then mounted onto a Miehle sheet-fed press using a wear ink containing 1.5% calcium carbonate to produce from only about 5,000 good impressions. The % of AM (amplitude modulation) screening at 200 lines per inch (508 lines/cm) was recorded by reading the 10% AM dots on press (that is, mesurement was made on paper/press-sheet) as a function of the number of the impression (See FIG. 1).

The invention has been described in detail with particular reference to certain preferred embodiments thereof, but it will be understood that variations and modifications can be effected within the spirit and scope of the invention.

1. A negative-working, infrared radiation-sensitive imageable element comprising a substrate having thereon a single outermost imageable layer comprising:
a) an infrared radiation absorbing compound,
b) a free radically polymerizable component,
c) an initiator composition capable of generating free radicals sufficient to initiate polymerization of free radically polymerizable groups upon exposure to imaging radiation,
d) a polymeric binder, and
e) an adhesion promoter that is an organic compound having an ethylenically unsaturated carbon-carbon double bond that is connected to an alkoxysilyl or hydroxysilyl group.

2. The element of claim 1 wherein said adhesion promoter is represented by the following Structure (I): 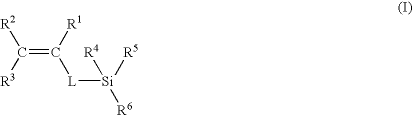
wherein R¹ to R³ are independently hydrogen or halogen or alkyl groups, R⁴ to R⁶ are independently hydrogen or halogen, hydroxy, alkyl, alkoxy, or aryl groups provided that at least one of R⁴ to R⁶ is a hydroxy or alkoxy group, and L is a direct bond or a divalent linking group.

3. The element of claim 2 wherein R¹ to R³ are independently hydrogen or methyl groups, and R⁴ to R⁶ are independently hydrogen or hydroxy, alkyl, alkoxy, or aryl groups provided that at least two of R⁴ to R⁶ are hydroxy, methoxy, or ethoxy groups.

4. The element of claim 2 wherein L is a direct bond or a linking group comprising one or more oxy, thio, alkylene, alkenylene, arylene, sulfonyl, carbonyl, substituted or unsubstituted amino, —CH(OH)—, —C(═O)—, —OC(═O)—, heterocyclylene groups, or any combination of two or more thereof.

5. The element of claim 2 wherein R¹ to R³ are independently hydrogen or methyl, R⁴ to R⁶ are independently hydrogen or hydroxy, methyl, ethyl, phenyl, methoxy, or ethoxy groups provided that at least two of R⁴ to R⁶ are methoxy or ethoxy groups, and L is a direct bond or a —(═O)—O—(CH₂)ₙ— linking group wherein n is 1 to 6.

6. The element of claim 1 wherein said substrate is a sulfuric acid-anodized aluminum-containing substrate having a hydrophilic surface upon which said imageable layer is disposed.

7. The element of claim 1 wherein said adhesion promoter is present in said imageable layer in an amount of at least 0.1 weight % and up to and including 12 weight %.

8. The element of claim 1 wherein said initiator composition comprises an onium salt.

9. The element of claim 8 wherein said initiator composition comprises an iodonium salt.

10. The element of claim 1 wherein said free radically polymerizable component comprises at least one ethylenically unsaturated free radically polymerizable monomer or oligomer, or free radically crosslinkable polymer.

11. A negative-working, infrared radiation-sensitive lithographic printing plate precursor comprising a sulfuric acid-anodized aluminum-containing substrate having thereon a single outermost imageable layer comprising:
a) an infrared radiation absorbing dye,
b) a free radically polymerizable monomer or oligomer, or free radically crosslinkable polymer,
c) an initiator composition comprising an iodonium salt and optionally a co-initiator,
d) a polymeric binder, and
e) one or more of vinyltrimethoxysilane, vinylmethyldimethoxy-silane, vinyltriethoxysilane, vinyltris(2-methoxyethoxy)silane, vinyltriacetyloxy-silane, 3-acryloxypropyltrimethoxysilane, and 3-methacryloxypropyltrimethoxy-silane, 3-methacryloxypropylmethyldimethoxysilane, in a total amount of from about 0.2 to about 8 weight %.

12. A method of making an imaged element comprising:
A) imagewise exposing the negative-working imageable element of claim 1 using imaging infrared radiation to produce exposed and non-exposed regions, and
B) with or without a post-exposure baking step, developing said imagewise exposed element off-press to remove predominantly only said non-exposed regions.

13. The method of claim 12 wherein step A is carried out using an infrared radiation-emitting laser and step B is carried out using an organic solvent-containing developer.

14. The method of claim 12 to provide a lithographic printing plate having a sulfuric acid-anodized aluminum-containing substrate.

15. The method of claim 12 wherein said negative-working imageable element comprises an adhesion promoter that is represented by the following Structure (I): 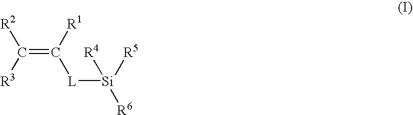
wherein R¹ to R³ are independently hydrogen or halogen, alkyl groups, R⁴ to R⁶ are independently hydrogen or halogen, hydroxy, alkyl, alkoxy, or aryl groups provided that at least one of R⁴ to R⁶ is a hydroxy or alkoxy group, and L is a direct bond or a divalent linking group.

16. The method of claim 15 wherein R¹ to R³ are independently hydrogen or methyl groups, and R⁴ to R⁶ are independently hydrogen or hydroxy, alkyl, alkoxy, or aryl groups provided that at least two of R⁴ to R⁶ are hydroxy, methoxy, or ethoxy groups.

17. The method of claim 12 wherein said negative-working imageable element is an infrared radiation-sensitive lithographic printing plate precursor comprising a sulfuric acid-anodized aluminum-containing substrate having thereon a single outermost imageable layer comprising:
a) an infrared radiation absorbing dye,
b) a free radically polymerizable monomer or oligomer, or free radically crosslinkable polymer,
c) an initiator composition comprising an iodonium salt and optionally a co-initiator,
d) a polymeric binder, and
e) one or more of vinyltrimethoxysilane, vinylmethyldimethoxysilane, vinyltriethoxysilane, vinyltris(2-methoxyethoxy)silane, vinyltriacetyloxysilane, 3-acryloxypropyltrimethoxysilane, and 3-methacryloxypropyltrimethoxysilane, 3-methacryloxypropylmethyldimethoxysilane in an amount of from about 0.2 to about 8 weight %.
